(19) United States
(12) Patent Application Publication
(10) Pub. No.: US 2018/0308663 A1
(43) Pub. Date: Oct. 25, 2018

(54) PLASMA REACTOR WITH PHASE SHIFT APPLIED ACROSS ELECTRODE ARRAY

(71) Applicants: Kenneth S. Collins, San Jose, CA (US); Kartik Ramaswamy, San Jose, CA (US); Yue Guo, Menlo Park, CA (US); Shahid Rauf, Pleasanton, CA (US); Kallol Bera, San Jose, CA (US); James D. Carducci, Sunnyvale, CA (US); Michael R. Rice, Pleasanton, CA (US)

(72) Inventors: Kenneth S. Collins, San Jose, CA (US); Kartik Ramaswamy, San Jose, CA (US); Yue Guo, Menlo Park, CA (US); Shahid Rauf, Pleasanton, CA (US); Kallol Bera, San Jose, CA (US); James D. Carducci, Sunnyvale, CA (US); Michael R. Rice, Pleasanton, CA (US)

(21) Appl. No.: 15/960,372

(22) Filed: Apr. 23, 2018

Related U.S. Application Data
(60) Provisional application No. 62/523,761, filed on Jun. 22, 2017.
(60) Provisional application No. 62/489,344, filed on Apr. 24, 2017.

(51) Int. Cl. H01J 37/32; C23C 16/455

(52) U.S. Cl. CPC H01J 37/32137; H01J 37/32091; H01J 37/32541; H01J 37/32449; H01L 21/67069; H01J 37/321; H01J 37/32568; C23C 16/45536; H01J 37/32715

(57) ABSTRACT

A plasma reactor includes a chamber body having an interior space that provides a plasma chamber, a gas distributor to deliver a processing gas to the plasma chamber, a pump coupled to the plasma chamber to evacuate the chamber, a workpiece support to hold a workpiece, an intra-chamber electrode assembly including a plurality of filaments extending laterally through the plasma chamber between a ceiling of the plasma chamber and the workpiece support, each filament including a conductor surrounded by a cylindrical insulating shell, and an RF power source configured to apply a first RF signal to at least some of the plurality of filaments, to apply a second RF signal of equal frequency to at least some of the plurality of filaments, and to modulate a phase offset between the first RF signal and the second RF signal.

### CROSS-REFERENCE TO RELATED APPLICATIONS

This application claims priority to U.S. Provisional Application Ser. No. 62/523,761, filed on Jun. 22, 2017, and U.S. Provisional Application Ser. No. 62/489,344, filed on Apr. 24, 2017, each of which is incorporated by reference.

### TECHNICAL FIELD

The present disclosure relates to a plasma reactor, e.g. for depositing a film on, etching, or treating a workpiece such as a semiconductor wafer.

### BACKGROUND

Plasma is typically generated using a capacitively-coupled plasma (CCP) source or an inductively-coupled plasma (ICP) source. A basic CCP source contains two metal electrodes separated by a small distance in a gaseous environment similar to a parallel plate capacitor. One of the two metal electrodes are driven by a radio frequency (RF) power supply at a fixed frequency while the other electrode is connected to an RF ground, generating an RF electric field between the two electrodes. The generated electric field ionizes the gas atoms, releasing electrons. The electrons in the gas are accelerated by the RF electric field and ionizes the gas directly or indirectly by collisions, producing plasma.

A basic ICP source typically contains a conductor in a spiral or a coil shape. When an RF electric current is flowed through the conductor, RF magnetic field is formed around the conductor. The RF magnetic field accompanies an RF electric field, which ionizes the gas atoms and produces plasma.

Plasmas of various process gasses are widely used in fabrication of integrated circuits. Plasmas can be used, for example, in thin film deposition, etching, and surface treatment.

Atomic layer deposition (ALD) is a thin film deposition technique based on the sequential use of a gas phase chemical process. Some ALD processes use plasmas to provide necessary activation energy for chemical reactions. Plasma-enhanced ALD processes can be performed at a lower temperature than non-plasma-enhanced (e.g., ‘thermal’) ALD processes.

### SUMMARY

In one aspect, a plasma reactor includes a chamber body having an interior space that provides a plasma chamber, a gas distributor to deliver a processing gas to the plasma chamber, a pump coupled to the plasma chamber to evacuate the chamber, a workpiece support to hold a workpiece, an intra-chamber electrode assembly including a plurality of filaments extending laterally through the plasma chamber between a ceiling of the plasma chamber and the workpiece support, and an RF power source. Each filament includes a conductor surrounded by a cylindrical insulating shell. The RF power source is configured to apply a first RF signal to at least some of the plurality of filaments, to apply a second RF signal of equal frequency to at least some of the plurality of filaments, and to modulate a phase offset between the first RF signal and the second RF signal.

Implementations may include one or more of the following features.

The plurality of filaments may have a plurality of first ends and a plurality of second ends, and a first end of each respective filament may be closer to a first sidewall of the plasma chamber than a second end of the respective filament. The first RF signal may be applied to the first ends of the plurality of filaments, and the second RF signal may applied to the second ends of the plurality of filaments. The first ends of the plurality of filaments may be connected to a first common bus, and the second ends of the plurality of filaments may be connected to a second common bus.

The plurality of filaments may include a first filament, a plurality of intermediate filaments, and a final filament, and the first RF signal may be applied to the first filament, and the second RF signal may applied to the final filament. Each intermediate filament may have a first end electrically connected to a second end of an adjacent filament and a second end electrically may be coupled to a first end of another adjacent filament. The connections may be outside the chamber.

The plurality of filaments may include a first multiplicity of filaments and a second multiplicity of filaments arranged in an alternating pattern with the first multiplicity of filaments, and the first RF signal may be applied to the first multiplicity of filaments and the second RF signal may be applied to the second multiplicity of filaments. The RF power source may be configured to apply the first RF input signal to the first ends of the first multiplicity of filaments and to apply the second RF signal to the second ends of the second multiplicity of filaments. The second ends of the first multiplicity of filaments may be floating and the first ends of the second multiplicity of filaments may be floating. The second ends of the first multiplicity of filaments may be grounded and the first ends of the second multiplicity of filaments may be grounded. The second ends of the first multiplicity of filaments may be electrically connected to the first ends of the second multiplicity of filaments.

A support to hold a top electrode in a ceiling of the chamber may be included. A bottom electrode in the workpiece support may be included.

The plurality of filaments may include a first multiplicity of filaments, and a first bus may be connected to first ends of the first multiplicity of filaments. The RF power source may be configured to apply the first RF signal to a first location on the first bus and to apply the second RF signal to a different second location on the bus. The first location and the second location may be on opposite ends of the bus. A second bus connected to opposite second ends of the first multiplicity of filaments may be included. The RF power source may be configured to apply the first RF signal to a first location on the first bus and to apply the second RF signal to a different second location on the second bus. The RF power source may be configured to apply the first RF signal to a different third location on the first bus and to apply the second RF signal to a different fourth location on the second bus.

The plurality of filaments may include a second multiplicity of filaments, and a third bus may be connected to first ends of the second multiplicity of filaments. The RF power source may be configured to apply the first RF signal to a first location on the first bus and a second location on the third bus, and to apply the second RF signal to a different third location on the first bus and a different fourth location on the third bus. A second bus may be connected to opposite second ends of the first multiplicity of filaments, and a fourth bus may be connected to opposite second ends of the second multiplicity of filaments. The RF power source may be configured to apply the first RF signal to a first location on the first bus and a second location on the second bus, and to apply the second RF signal to a third location on the third bus and a fourth location on the fourth bus. The RF power source may be configured to apply the first RF signal to a first location and a different second on the first bus and to a third location and a different fourth location on the second bus, and to apply the second RF signal to a fifth location and a different sixth location on the third bus and to a seventh location and a different eighth location on the fourth bus. The first, third, fifth and seventh locations may be on opposite ends of respective busses from the second, fourth, sixth and eighth locations, respectively.

The RF power source may be configured to modulate the phase offset so as to vary a standing wave pattern of voltage on the conductors over time. The plurality of filaments may include a plurality of coplanar filaments. The plurality of coplanar filaments may include linear filaments. The plurality of coplanar filaments may extend in parallel through the plasma chamber. The plurality of coplanar filaments may be uniformly spaced apart.

In another aspect, a method of processing a workpiece includes positioning the workpiece on a workpiece support such that a front surface of the workpiece faces a plurality of filaments that extend laterally through a plasma chamber between a ceiling of the plasma chamber and the workpiece support, delivering a process gas to the plasma chamber, applying a first RF signal to at least some of the plurality of filaments and applying a second RF signal of equal frequency to at least some of the plurality of filaments so as to generate a plasma in the plasma chamber and the workpiece is exposed to the plasma from the plasma chamber; and modulating a phase offset between the first RF signal and the second RF signal.

Implementations may include one or more of the following features. Modulating the phase offset may vary a standing wave pattern of voltage on the conductors over time. The phase offset between the first RF signal and the second RF signal may be modulated so as to increase plasma density uniformity. The phase offset between the first RF signal and the second RF signal may be modulated so as to induce a plasma density non-uniformity to compensate for a non-uniformity of a layer on the substrate or a source of non-uniformity of processing of the layer. Applying the first RF signal and the second RF signal may include differentially applying RF power to a first multiplicity of filaments and a second multiplicity of filaments through a matching network and a balun. The first multiplicity of filaments and the second multiplicity of filaments may be arranged in an alternating pattern in the plasma chamber.

Certain implementations may have one or more of the following advantages. Plasma uniformity may be improved. Plasma process repeatability may be improved. Metal contamination may be reduced. Particle generation may be reduced. Plasma charging damage may be reduced. Uniformity of plasma may be maintained over different process operating conditions. Plasma power coupling efficiency may be improved. Non-uniformity in plasma density, e.g., due to standing waves may be reduced. Non-uniformity due to processing conditions or an initial state of a workpiece may be mitigated.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a schematic side view diagram of an example of a plasma reactor.

FIG. 2A is a schematic top view diagram of a processing tool that includes a plasma reactor.

FIGS. 2B and 2C are schematic side views of the plasma reactor of FIG. 2A along lines 2B-2B and 2C-2C, respectively.

FIGS. 3A-3C are schematic cross-sectional perspective view diagrams of various examples of a filament of an intra-chamber electrode assembly.

FIG. 4A is a schematic top view diagram of a portion of an intra-chamber electrode assembly.

FIGS. 4B-4C are cross-sectional schematic side view diagrams of an intra-chamber electrode assembly with different plasma region states.

FIGS. 5A-5E are schematic top view diagrams of various examples of electrode assembly configurations.

FIGS. 6A-6B are a schematic top view diagram of portions of an intra-chamber electrode assembly.

FIG. 7A is a schematic top view diagram of an exemplary electrode assembly configuration.

FIGS. 7B-7D are schematics showing phase modulation of two input signals as a function of time.

FIGS. 7E and 7F are schematic top view diagram of additional exemplary electrode assembly configurations.

FIG. 8A is a schematic top view diagram of an exemplary electrode assembly configuration.

FIG. 8B is a schematic showing phase modulation of two input signals as a function of time.

FIG. 8C is a schematic top view diagram of another exemplary electrode assembly configuration.

FIG. 9A-9B are exemplary circuit schematics for generating multiple input signals modulated in phase as a function of time.

FIG. 10 is an exemplary circuit schematic for generating multiple input signals of different frequencies.

FIG. 11 is an exemplary circuit schematic for generating a single input signal of one frequency.

Like reference symbols in the various drawings indicate like elements.

### DETAILED DESCRIPTION

Plasma uniformity in a conventional CCP source is typically determined by electrode(s) size and inter-electrode distance, as well as by gas pressure, gas composition, and applied RF power. At higher radio frequencies, additional effects may become significant or even dominate non-uniformities due to the presence of standing waves or skin effects. Such additional effects become more pronounced at higher frequencies and plasma densities.

Plasma uniformity in a conventional ICP source is typically determined by the configuration of ICP coil(s) including its size, geometry, distance to workpiece, and associated RF window location, as well as by gas pressure, gas composition, and power. In case of multiple coils or coil segments, the current or power distribution and their relative phase, if driven at same frequency, might also be a significant factor. Power deposition tends to occur within several centimeters under or adjacent to ICP coils due to skin effect, and such localized power deposition typically leads to process non-uniformities that reflect the coil geometries. Such plasma non-uniformity causes a potential difference across a workpiece, which can also lead to plasma charging damage (e.g., transistor gate dielectric rupture).

A large diffusion distance is typically needed for improved uniformity of ICP source. However, a conventional ICP source with a thick RF window is typically inefficient at high gas pressures due to low power coupling, which leads to high drive current resulting in high resistive power losses. In contrast, an intra-chamber electrode assembly does not need to have an RF window, but only a thin cylindrical shell. This can provide better power coupling and efficiency.

Where an array of elongated conductors is used, another source of non-uniformity is standing waves of RF energy along the conductors. Internal reflections from the various circuitry can generate standing waves of RF energy; this can generate “hot spots” and thus non-uniformity in the electrode.

A plasma source with an intra-chamber electrode assembly may be able to provide one or more of the following: efficient production of a uniform plasma with the desired properties (plasma density, electron temperature, ion energy, dissociation, etc.) over the workpiece size; tunability for uniformity over the operating window (e.g. pressure, power, gas composition); stable and repeatable electrical performance even with a moving workpiece; and avoidance of excessive metal contaminants or particles.

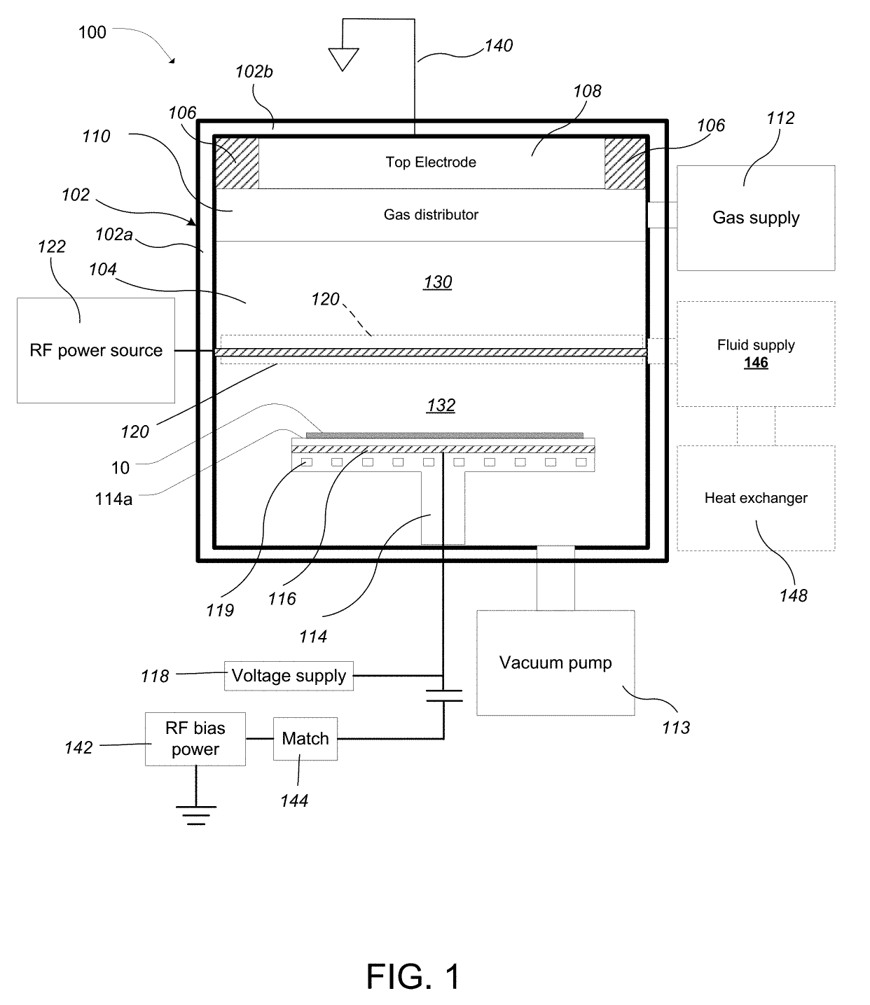

FIG. 1 is a schematic side view diagram of an example of a plasma reactor. A plasma reactor 100 has a chamber body 102 enclosing an interior space 104 for use as a plasma chamber. The chamber body 102 can have one or more side walls 102a and a ceiling 102b. The interior space 104 can be cylindrical, e.g., for processing of circular semiconductor wafers. The chamber body 102 has a support 106 located near the ceiling of the plasma reactor 100, which supports a top electrode 108. The top electrode can be suspended within the interior space 104 and spaced from the ceiling, abut the ceiling, or form a portion of the ceiling. Some portions of the side walls of the chamber body 102 can be separately grounded.

A gas distributor 110 can be located near the ceiling of the plasma reactor 100. In some implementations, the gas distributor 110 is integrated with the top electrode 108 as a single component. Alternatively, the gas distributor 110 can include one or more ports in the side wall 102a of the chamber. The gas distributor 110 is connected to a gas supply 112. The gas supply 112 delivers one or more process gases to the gas distributor 110, the composition of which can depend on the process to be performed, e.g., deposition or etching. A vacuum pump 113 is coupled to the interior space 104 to evacuate the plasma reactor. For some processes, the chamber is operated in the Torr range, and the gas distributor 110 supplies argon, nitrogen, oxygen and/or other gases.

Depending on chamber configuration and supplied processing gasses, the plasma reactor 100 could provide an ALD apparatus, an etching apparatus, a plasma treatment apparatus, a plasma-enhanced chemical vapor deposition apparatus, a plasma doping apparatus, or a plasma surface cleaning apparatus.

A workpiece support pedestal 114 for supporting a workpiece 10 is positioned in the plasma reactor 100. The workpiece support pedestal 114 has a workpiece support surface 114a facing the top electrode 108. In some implementations, the workpiece support pedestal 114 includes a workpiece support electrode 116 inside the pedestal 114, and a workpiece bias voltage supply 118 is connected to the workpiece support electrode 116. The voltage supply 118 can apply a voltage to chuck the workpiece 115 to the pedestal 114 and/or supply a bias voltage to control characteristics of the generated plasma, including the ion energy. In some implementations, an RF bias power generator 142 is AC-coupled through an impedance match 144 to the workpiece support electrode 116 of the workpiece support pedestal 114.

Additionally, the pedestal 114 can have internal passages 119 for heating or cooling the workpiece 115, and/or an embedded resistive heater (119).

An intra-chamber electrode assembly 120 is positioned in the interior space 104 between the top electrode 108 and the workpiece support pedestal 114. This electrode assembly 120 includes one or more filaments that extend laterally in the chamber over the support surface 114a of the pedestal 114. At least a portion of the filaments of the electrode assembly 120 over the pedestal 114 extends parallel to the support surface 114a. A top gap 130 is formed between the top electrode 108 and the intra-chamber electrode assembly 120. A bottom gap 132 is formed between the workpiece support pedestal 114 and the intra-chamber electrode assembly 120.

The electrode assembly 120 is driven by an RF power source 122. The RF power source 122 can apply power to the one or more filaments of the electrode assembly 120 at frequencies of 1 to 300 MHz or higher. For some processes, the RF power source 120 provides a total RF power of about 100 W to more than 2 kW at a frequency of 60 MHz.

In some implementations, it may be desirable to select the bottom gap 132 to cause a plasma generated radicals, ions or electrons to interact with the workpiece surface. The selection of gap is application-dependent and operating regime dependent. For some applications wherein it is desired to deliver a radical flux (but very low ion/electron flux) to the workpiece surface, operation at larger gap and/or higher pressure may be selected. For other applications wherein it is desired to deliver a radical flux and substantial plasma ion/electron flux) to the workpiece surface, operation at smaller gap and/or lower pressure may be selected. For example, in some low-temperature plasma-enhanced ALD processes, free radicals of process gases are necessary for the deposition or treatment of an ALD film. A free radical is an atom or a molecule that has an unpaired valence electron. A free radical is typically highly chemically reactive towards other substances. The reaction of free radicals with other chemical species often plays an important role in film deposition. However, free radicals are typically short-lived due to their high chemical reactivity, and therefore cannot be transported very far within their lifetime. Placing the source of free radicals, namely the intra-chamber electrode assembly 120 acting as a plasma source, close to the surface of the workpiece 115 can increase the supply of free radicals to the surface, improving the deposition process.

The lifetime of a free radical typically depends on the pressure of the surrounding environment. Therefore, a height of the bottom gap 132 that provides satisfactory free radical concentration can change depending on the expected chamber pressure during operation. In some implementations, if the chamber is to be operated at a pressure in the range of 0.01-10 Ton, the bottom gap 132 is less than 1 cm.1-10 Torr, the bottom gap 132 is less than 1 cm. In other low(er) temperature plasma-enhanced ALD processes, exposure to plasma ion flux (and accompanying electron flux) as well as radical flux may be necessary for deposition and treatment of an ALD film. In some implementations, if the chamber is to be operated at a pressure in the range of 1-10 Torr, the bottom gap 132 is less than 0.5 cm. Lower operating pressures may allow for operation at larger gaps due to lower volume recombination rate with respect to distance. In other applications, such as etching, lower operating pressure is typically used (less than 100 mTorr) and the gap may be increased.

In such applications where the bottom gap 132 is small, the plasma generated by the electrode assembly 120 can have significant non-uniformities between the filaments, which may be detrimental to processing uniformity of the workpiece. By moving the workpiece through the plasma having spatial non-uniformities, the effect of the plasma spatial non-uniformities on the process can be mitigated by a time-averaging effect, i.e., the cumulative plasma dose received by any given region of the workpiece after a single pass through the plasma is substantially similar.

The top gap may be selected large enough for plasma to develop between intra-chamber electrode assembly and top electrode (or top of chamber). In some implementations, if the chamber is to be operated at a pressure in the range of 1-10 Torr, the top gap 130 may be between 0.5-2 cm, e.g., 1.25 cm.

The top electrode 108 can be configured in various ways. In some implementations, the top electrode is connected to an RF ground 140. In some implementations, the top electrode is electrically isolated (‘floating’). In some implementations, the top electrode 108 is biased to a bias voltage. The bias voltage can be used to control characteristics of the generated plasma, including the ion energy. In some implementations, the top electrode 108 is driven with an RF signal. For example, driving the top electrode 108 with respect to the workpiece support electrode 116 that has been grounded can increase the plasma potential at the workpiece 115. The increased plasma potential can cause an increase in ion energy to a desired value.

The top electrode 108 can be formed of different process-compatible materials. Various criteria for process-computability include a material's resistance to etching by the process gasses and resistance to sputtering from ion bombardment. Furthermore, in cases where a material does get etched, a process-compatible material preferably forms a volatile, or gaseous, compound which can be evacuated by the vacuum pump 113, and not form particles that can contaminate the workpiece 115. Accordingly, in some implementations, the top electrode is made of silicon. In some implementations, the top electrode is made of silicon carbide.

In some implementations, the top electrode 108 may be omitted. In such implementations, RF ground paths may be provided by the workpiece support electrode or by a subset of coplanar filaments of the electrode assembly 120.

In some implementations, a fluid supply 146 circulates a fluid through channels in the intra-chamber electrode assembly 120. In some implementations, a heat exchanger 148 is coupled to the fluid supply 146 to remove or supply heat to the fluid.

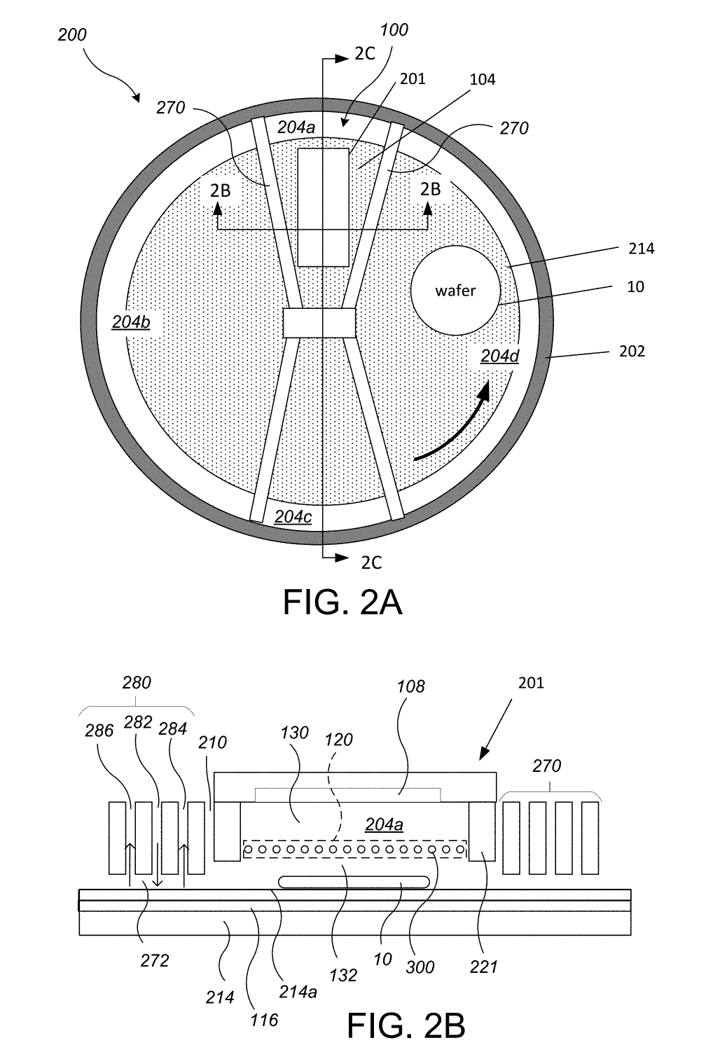

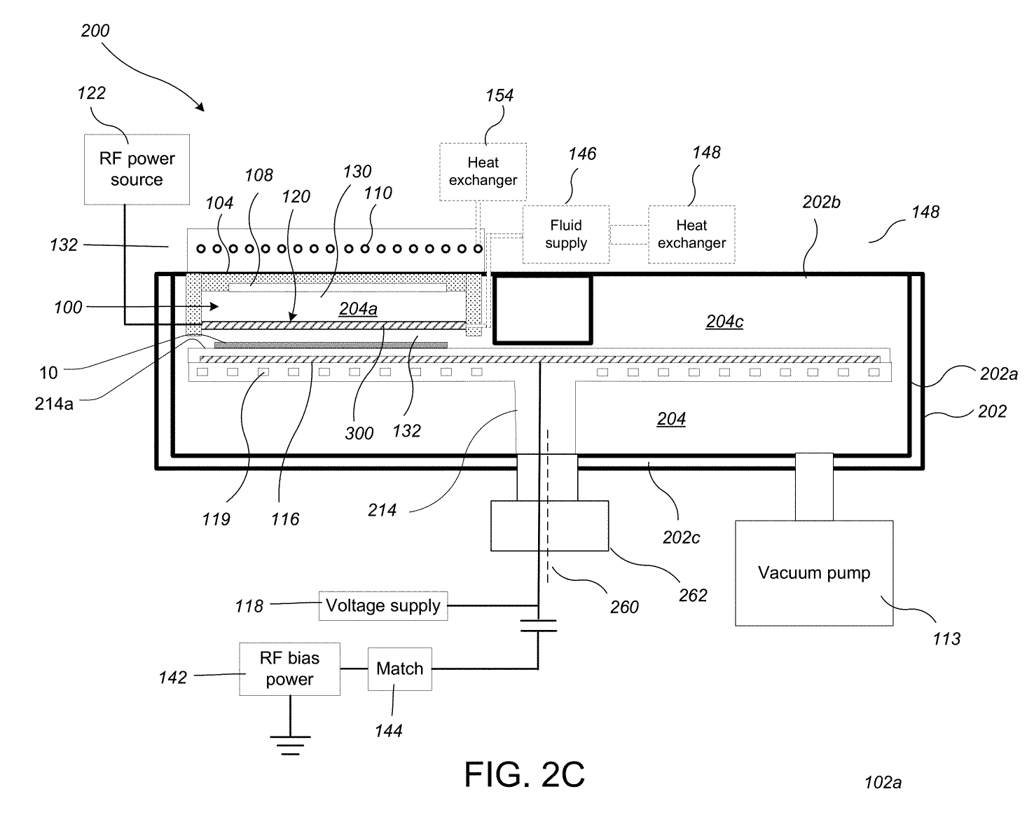

FIGS. 2A-2C are schematic views of another example of a plasma reactor. In this example, a multi-chamber processing tool 200 includes a plasma reactor 100. Here, the intra-chamber electrode assembly 120 can be part of an electrode unit 201 that can also include the top electrode 108.

The processing tool 200 has a body 202 enclosing an interior space 204. The body 202 can have one or more side walls 202a, a ceiling 202b and a floor 202c. The interior space 204 can be cylindrical.

The processing tool 200 includes a workpiece support 214, such as a pedestal, for supporting one or more workpieces 115, e.g., a plurality of workpieces. The workpiece support 214 has a workpiece support surface 214a. The workpiece support 214 can include the workpiece support electrode 116, and a workpiece bias voltage supply 118 can be connected to the workpiece support electrode 116.

A space between the top of the workpiece support 214 and the ceiling 202b can be divided into a plurality of chambers 204a-204d by barriers 270. The barriers 270 can extend radially from a center of the workpiece support 214. Although four chambers are illustrated, there could be two, three or more than four chambers.

The workpiece can be rotatable about an axis 260 by a motor 262. As a result, any workpiece 115 on the workpiece support 214 will be carried sequentially through the chambers 204a-204d.

The chambers 204a-204d can be at least partially isolated from each other by a pump-purge system 280. The pump-purge system 280 can include multiple passages formed through the barrier 210 that flow a purge gas, e.g., an inert gas such as argon, into a space between adjacent chambers, and/or pump gas out of a space between adjacent chambers. For example, the pump-purge system 280 can include a first passage 282 though which a purge gas is forced, e.g., by a pump, into the space 202 between the barrier 270 and the workpiece support 214. The first passage 282 can be flanked on either side (relative to direction of motion of the workpiece support 214) by a second passage 284 and a third passage 286 which are connected to a pump to draw gas, include both the purge gas and any gas from the adjacent chamber, e.g., chamber 204a. Each passage can be an elongated slot that extends generally along the radial direction.

At least one of the chambers 204a-204d provides a plasma chamber of a plasma reactor 100. The plasma reactor includes the top electrode array assembly 120 and RF power source 122, and can also include the fluid supply 146 and/or heat exchanger. Process gas can be supplied through a port 210 located along one or both barriers 270 to the chamber 104. In some implementations, the port 210 is positioned only on the leading side of the chamber 104 (relative to direction of motion of the workpiece support 214). Alternatively or in addition, process gas can be supplied through ports the side wall 202a of the tool body 202.

With respect to either FIG. 1 or FIGS. 2A-2C, the electrode assembly 120 or 220 includes one or more coplanar filaments 300 that extend laterally in the chamber over the support surface of the workpiece support. At least a portion of the coplanar filaments of the electrode assembly over the workpiece support extends parallel to the support surface. The filaments 300 can be at a non-zero angle relative to direction of motion, e.g., substantially perpendicular to direction of motion. Each filament can include a conductor surrounded by a cylindrical shell of process-compatible material.

The electrode unit 201 can include side walls 221 that surround the electrode plasma chamber region. The side walls can be formed of a process-compatible material, e.g., quartz. In some implementations, the filaments project laterally out the side walls 221. In some implementations, the filaments 300 extend, e.g., vertically, out of the ceiling of the electrode unit 201 and turn horizontally to provide the portion that is parallel to the support surface for the workpiece (see FIG. 2C).

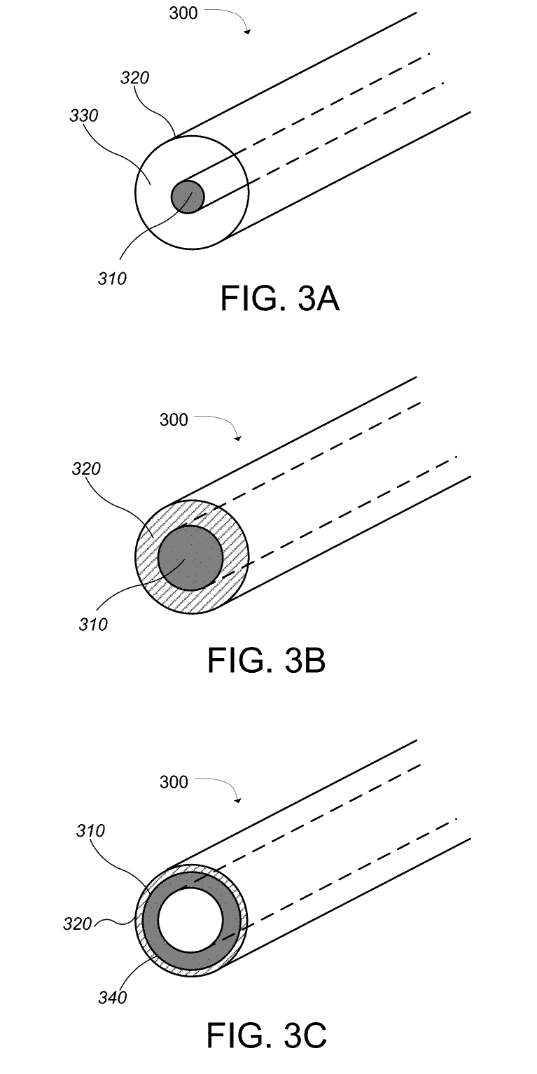

FIGS. 3A-3C are schematic diagrams of various examples of a filament of an intra-chamber electrode assembly. Referring to FIG. 3A, a filament 300 of the intra-chamber electrode assembly 120 is shown. The filament 300 includes a conductor 310 and an annular shell 320, e.g., a cylindrical shell, that surrounds and extends along the conductor 310. A conduit 330 is formed by the gap between the conductor 310 and the shell 320. The shell 320 is formed of a non-metallic material that is compatible with the process. In some implementations, the shell is semiconductive. In some implementations, the shell is insulative.

The conductor 310 can be formed of various materials. In some implementations, the conductor 310 is a solid wire, e.g., a single solid wire with a diameter of 0.063″.Alternatively, the conductor 310 can be provided by multiple stranded wires. In some implementations, the conductor contains 3 parallel 0.032″ stranded wires. Multiple stranded wires can reduce RF power losses through skin effect.

A material with high electrical conductivity, e.g., above 10⁷ siemen/m, is used, which can reduce resistive power losses. In some implementations, the conductor 310 is made of copper or an alloy of copper. In some implementations, the conductor is made of aluminum.

Undesired material sputtering or etching can lead to process contamination or particle formation. Whether the intra chamber electrode assembly 120 is used as a CCP or an ICP source, undesired sputtering or etching can occur. The undesired sputtering or etching may be caused by excessive ion energy at the electrode surface. When operating as a CCP source, an oscillating electric field around the electrode shell is necessary to drive the plasma discharge. This oscillation leads to sputtering or etching of materials, as all known materials have a sputtering energy threshold that is lower than the corresponding minimum operating voltage of a CCP source. When operated as an ICP source, capacitive coupling of the filament 300 to the plasma creates an oscillating electric field at nearby surfaces, which also causes sputtering of materials. The problems resulting from undesired material sputtering or etching may be mitigated by using a process-compatible material for the outer surface of the filament 300 exposed to the interior space 104 (e.g., the shell 320).

In some implementations, the shell 320 is formed of a process-compatible material such as silicon, e.g., a high resistivity silicon, an oxide material, a nitride material, a carbide material, a ceramic material, or a combination thereof. Examples of oxide materials include silicon dioxide (e.g., silica, quartz) and aluminum oxide (e.g., sapphire). Examples of carbide materials include silicon carbide. Ceramic materials or sapphire may be desirable for some chemical environments including fluorine-containing environments or fluorocarbon containing environments. In chemical environments containing ammonia, dichlorosilane, nitrogen, and oxygen, use of silicon, silicon carbide, or quartz may be desirable.

In some implementations, the shell 320 has a thickness 0.1 to 3 mm, e.g., 1 mm.

In some implementations, a fluid is provided in the conduit 330. In some implementations, the fluid is a non-oxidizing gas to purge oxygen to mitigate oxidization of the conductor 310. Examples of non-oxidizing gases are nitrogen and argon. In some implementations, the non-oxidizing gas is continuously flowed through the conduit 330, e.g., by the fluid supply 146, to remove residual oxygen.

The heating of conductor 310 can make the conductor more susceptible to oxidization. The fluid can provide cooling to the conductor 310, which may heat up from supplied RF power. In some implementations, the fluid is circulated through the conduit 330, e.g., by the fluid supply 146, to provide forced convection temperature control, e.g., cooling or heating.

In some implementations, the fluid may be at or above atmospheric pressure to prevent breakdown of the fluid.

Referring to FIG. 3B, in some implementations of the filament 300, the conductor 310 has a coating 320. In some implementations, the coating 320 is an oxide of the material forming the conductor (e.g., aluminum oxide on an aluminum conductor). In some implementations, the coating 320 is silicon dioxide. In some implementations, the coating 320 is formed in-situ in the plasma reactor 100 by, for example, a reaction of silane, hydrogen, and oxygen to form a silicon dioxide coating. In-situ coating may be beneficial as it can be replenished when etched or sputtered.

Referring to FIG. 3C, in some implementations of the filament 300, the conductor 310 is hollow, and a hollow conduit 340 is formed inside the conductor 310. In some implementations, the hollow conduit 340 can carry a fluid as described in FIG. 3A. A coating 320 of the process-compatible material can cover the conductor 310 to provide the cylindrical shell. In some implementations, the coating 320 is an oxide of the material forming the conductor (e.g., aluminum oxide on an aluminum conductor).

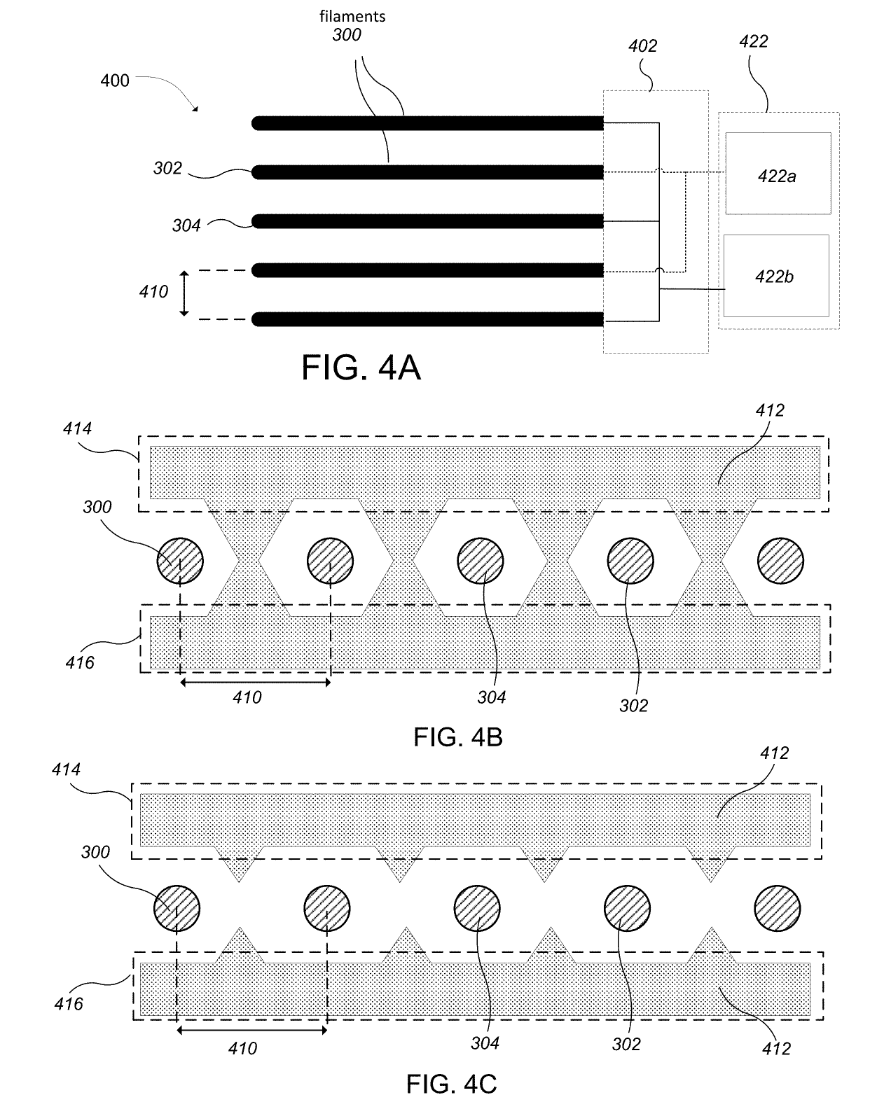

FIG. 4A is a schematic diagram of a portion of an intra-chamber electrode assembly. An intra-chamber electrode assembly 400 includes multiple coplanar filaments 300 attached at a support 402. The electrode assembly 400 can provide the electrode assembly 120. In some implementations, at least over the region corresponding to where the workpiece is processed, the filaments 300 extend in parallel to each other.

The filaments 300 are separated from one another by a filament spacing 410. The filament spacing 510 is the pitch; for parallel filaments the spacing can be measured perpendicular to the longitudinal axis of the filaments. The spacing 410 can impact plasma uniformity. If the spacing is too large, then the filaments can create shadowing and non-uniformity. On the other hand, if the spacing is too small, the plasma cannot migrate between the top gap 130 and the bottom gap 132, and non-uniformity will be increased and/or free radical density will be reduced. In some implementations, the filament spacing 410 is uniform across the assembly 400.

The filament spacing 510 can be 3 to 20 mm, e.g., 8 mm. At high pressure say 2-10 torr in N2, spacing range may be 20 mm to 3 mm. A compromise over the pressure range may be 5-10 mm. At lower pressure and greater distance to workpiece larger spacing may be effectively used.

FIGS. 4B-C are cross-sectional schematic diagrams of an intra-chamber electrode assembly with different plasma region states. Referring to FIG. 4B, a plasma region 412 surrounds the filaments 300. The plasma region 412 has an upper plasma region 414 and a lower plasma region 416. The upper plasma region 414 can be located at the top gap 130 and the lower plasma region 416 can be located at the bottom gap 132. As shown in FIG. 4B, the upper plasma region 414 and the lower plasma region 416 is connected through the gaps between the filaments 300, forming a continuous plasma region 412. This continuity of the plasma regions 412 is desirable, as the regions 414 and 416 ‘communicate’ with each other through exchange of plasma. The exchanging of plasma helps keep the two regions electrically balanced, aiding plasma stability and repeatability.

Referring to FIG. 4C, in this state, the upper plasma region 414 and the lower plasma region 416 is not connected to each other. This ‘pinching’ of the plasma region 412 is not desirable for plasma stability. The shape of the plasma region 412 can be modified by various factors to remove the plasma region discontinuity or improve plasma uniformity.

In general, the regions 412, 414, and 416 can have a wide range of plasma densities, and are not necessarily uniform. Furthermore, the discontinuities between the upper plasma region 414 and the lower plasma region 416 shown in FIG. 4C represents a substantially low plasma density relative to the two regions, and not necessarily a complete lack of plasma in the gaps.

The top gap 130 is a factor affecting the shape of the plasma region. Depending on the pressure, when the top electrode 108 is grounded, reducing the top gap 130 typically leads to a reduction of plasma density in the upper plasma region 414. Specific values for the top gap 130 can be determined based on computer modelling of the plasma chamber. For example, the top gap 130 can be 3 to 8 mm, e.g., 4.5 mm.

The bottom gap 132 is a factor affecting the shape of the plasma region. Depending on the pressure, when the workpiece support electrode 116 is grounded, reducing the bottom gap 132 typically leads to a reduction of plasma density in the lower plasma region 416. Specific values for the bottom gap 132 can be determined based on computer modelling of the plasma chamber. For example, the bottom gap 132 can be 3 to 9 mm, e.g., 4.5 mm. The bottom gap 132 can be equal to or smaller than the top gap 130.

In some implementations, the intra-chamber electrode assembly 400 can include a first group and a second group of filaments 300. The first group and the second group can be spatially arranged such that the filaments alternate between the first group and the second group. For example, the first group can include the filament 302, the second group can include the filament 304. The first group can be driven by a first terminal 422a of an RF power supply 422 and the second group can be driven by a second terminal 422b of the RF power supply 422.

The RF power supply 422 can be configured to provide a first RF signal at the terminal 422a and a second RF signal at terminal 422b. The first and second RF signals can have the same frequency and a stable phase relationship to each other. For example, the phase difference can be 0 degrees or 180 degrees. In some implementations, the phase difference between the first and the second RF signals provided by the RF power supply 422 can be tunable between 0 and 360 degrees.

To generate the signals, an unbalanced output signal from RF power supply can be coupled to a balun (a balance-unbalance transformer, not shown) to output balanced (‘differential’) signals on the terminals 422a, 422b. Alternatively, the RF supply 422 can include two individual RF power supplies that are phase-locked to each other.

The phase of the RF signal driving adjacent filaments 302, 304 is a factor affecting the shape of the plasma region. When the phase difference of the two RF signals driving the adjacent filaments 422a, 422b is set to 0 degrees (‘monopolar’, or ‘singled-ended’), the plasma region is pushed out from the gaps between the filaments 300, leading to discontinuity or non-uniformity, as shown in FIG. 4C. When the phase difference of the RF signals driving the adjacent filaments is set to 180 degrees (‘differential’), the plasma region is more strongly confined between the filaments 300. Any phase difference between 0 and 360 degrees can be used to affect the shape of the plasma region 412.

The grounding of the workpiece support electrode 116 is a factor affecting the shape of the plasma region. Imperfect RF grounding of the electrode 116 in combination with 0 degrees of phase difference between the RF signals driving the adjacent filaments pushes the plasma region towards the top gap. However, if adjacent filaments, e.g., filaments 302 and 304 are driven with RF signals that have 180 degrees of phase difference, the resulting plasma distribution is much less sensitive to imperfect RF grounding of the electrode 116. Without being limited to any particular theory, this can be because the RF current is returned through the adjacent electrodes due to the differential nature of the driving signals.

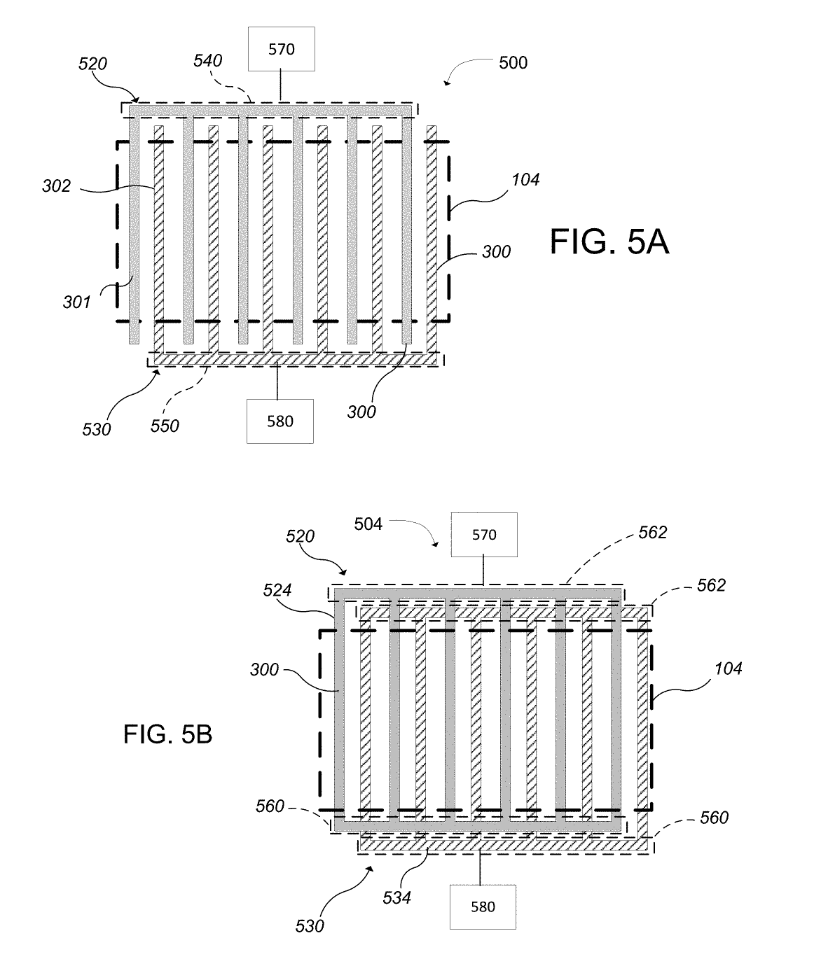

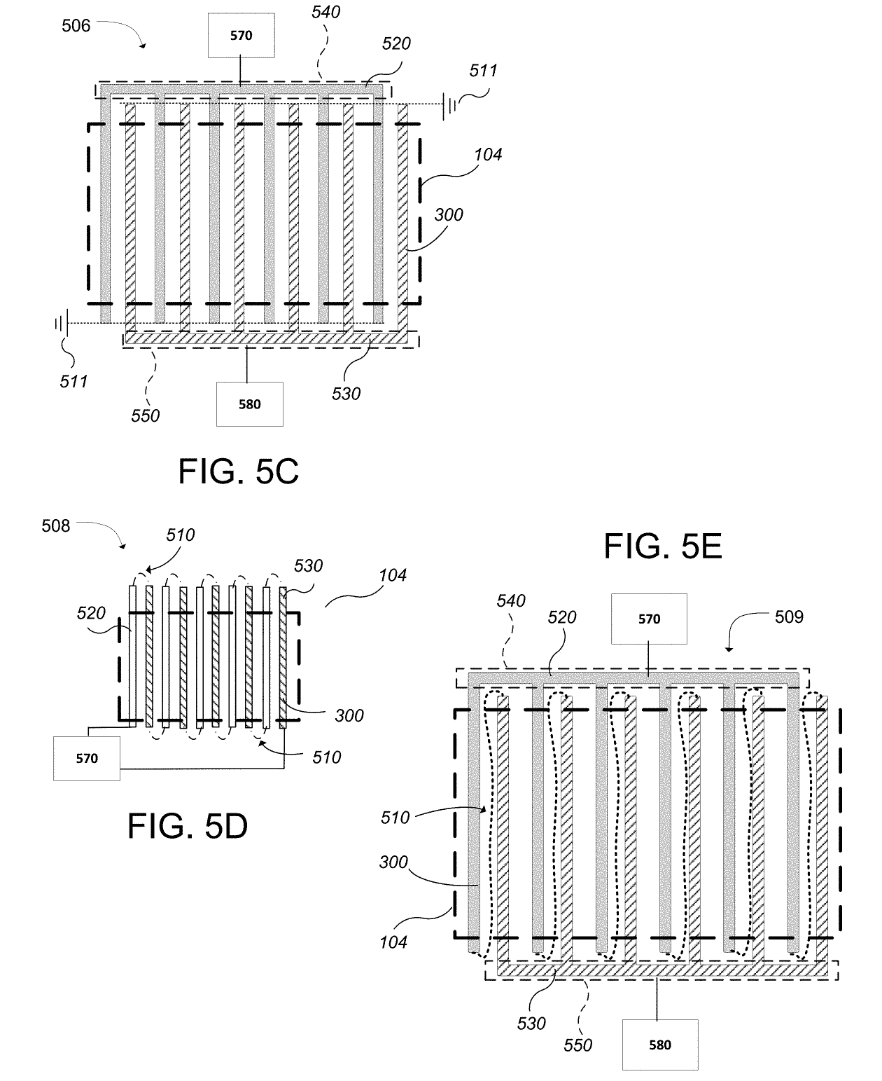

FIGS. 5A-E are schematic diagrams of various examples of intra-chamber electrode assembly configurations. The electrode assemblies 500, 504, 506, 508, 509 can provide the electrode assembly 120, and the filaments 300 can provide the filaments of the electrode assembly 120. Referring to FIG. 5A, an intra-chamber electrode assembly 500 includes a first electrode subassembly 520 that includes the first group of filaments and a second electrode subassembly 530 that includes the second group of filaments. The filaments of the first electrode subassembly 520 are interdigited with the filaments of the second electrode subassembly 530.

The subassemblies 520, 530 each have multiple parallel filaments 300 that extend across the chamber 104. Every other filament 301 is connected to a first bus 540 on one side of the chamber 104. The remaining (alternating) filaments 302 are each connected to a second bus 550 on the other side of the chamber 104. The end of each conductor 120 that is not connected to an RF power supply bus can be left unconnected, e.g., floating.

In some implementations, the buses 540, 550 connecting the filaments 300 are located outside of the interior space 104. In some implementations, the buses 540, 550 connecting the filaments 300 are located in the interior space 104. The first electrode subassembly 520 and the second electrode subassembly 530 are oriented parallel to each other such that the filaments of the subassemblies 520 and 530 are parallel to each other.

The intra-chamber electrode assembly 500 can be driven with RF signals in various ways. In some implementations, the subassembly 520 is driven by input 570 and subassembly 530 is driven by input 580. In some assemblies, inputs 570 and 580 are driven with a same RF signal with respect to an RF ground. In some implementations, the subassembly 520 and subassembly 530 are driven with a differential RF signal. In some implementations, the subassembly 520 and subassembly 530 are driven with two RF signals of the same frequency but a phase difference between 0 and 360 degrees, e.g., 0 or 180 degrees. In some implementations, the phase difference is modulated over time. In some implementations, the subassembly 520 is driven with an RF signal, and subassembly 530 is connected to an RF ground.

Referring to FIG. 5B, an intra-chamber electrode assembly 504 includes a first electrode subassembly 524 and a second electrode subassembly 534. The first electrode subassembly 524 and the second electrode subassembly 534 each has multiple filaments 300 that extend across the chamber 104. The set of filaments 300 of each subassembly are separately connected by buses 560 and 562 at both ends. The first electrode subassembly 524 and the second electrode subassembly 534 are configured such that the filaments of the subassemblies 524 and 534 are in alternating pattern. The filaments 300 can be parallel to each other.

In some implementations, the buses 560, 562 connecting the filaments 300 are located outside of the interior space 104. In some implementations, the buses 560, 562 connecting the filaments 300 are located in the interior space 104.

The intra-chamber electrode assembly 504 can be driven with RF signals in various ways. In some implementations, the subassembly 520 is driven by input 570 and subassembly 530 is driven by input 580. In some assemblies, inputs 570 and 580 are driven with a same RF signal with respect to an RF ground. In some implementations, the subassembly 520 and subassembly 530 are driven with a differential RF signal. In some implementations, the subassembly 520 and subassembly 530 are driven with two different RF signals of the same frequency with a phase difference between 0 and 360 degrees, e.g., 0 or 180 degrees. In some implementations, the phase difference is modulated over time. In some implementations, the subassembly 520 is driven with an RF signal, and subassembly 530 is connected to an RF ground.

Referring to FIG. 5C, an intra-chamber electrode assembly 506 includes a first electrode subassembly 520 and a second electrode subassembly 530. The first electrode subassembly 520 and the second electrode subassembly 530 each has multiple parallel filaments 300 that are connected by respective buses 540, 550 at one end. In some implementations, the filaments 300 of the first electrode subassembly are connected to the bus 540 at a proximal end of the filaments, and the filaments 300 of the second electrode subassembly are connected to the bus 550 at an opposite distal end of the filaments.

The ends of the first electrode subassembly 520 that are not connected to the bus 540 are electrically connected to a common ground 511, and the ends of the second electrode subassembly 530 that are not connected to the bus 550 are electrically connected to a common ground 511. For example, the distal ends of the filaments of the first electrode assembly can be electrically connected to the common ground 511, and the proximal ends of the filaments of the second electrode assembly can be electrically connected to the common ground 511.

In some implementations, the filaments of the first electrode subassembly are connected, e.g. at the distal end, to another bus that is connected the common ground 511, and the filaments of the second electrode sub assembly are connected, e.g., at the proximal end, to another bus that is connected the common ground 511.

The first electrode subassembly 520 and the second electrode subassembly 530 are configured such that the filaments of the subassemblies 520 and 530 arranged in alternating pattern. The filaments 300 can be parallel to each other.

The intra-chamber electrode assembly 506 can be driven with RF signals in various ways. In some implementations, the subassembly 520 is driven by input 570, e.g., to bus 540, and subassembly 530 is driven by input 580, e.g., to bus 550. In some assemblies, inputs 570 and 580 are driven with a same RF signal with respect to an RF ground. In some implementations, the subassembly 520 and subassembly 530 are driven with a differential RF signal. In some implementations, the subassembly 520 and subassembly 530 are driven with two different RF signals, of the same frequency, with a phase difference between 0 and 360 degrees. In some implementations, the phase difference is modulated over time.

Referring to FIG. 5D, an intra-chamber electrode assembly 508 includes a first electrode subassembly 520 and a second electrode subassembly 530. The first electrode subassembly 520 and the second electrode subassembly 530 each has multiple parallel filaments 300. The first electrode subassembly 520 and the second electrode subassembly 530 are configured such that the filaments of the subassemblies 520 and 533 are arranged in alternating pattern. The filaments 300 can be parallel to each other. In some implementations, the adjacent ends of the alternating filament pairs are electrically connected in series, with the connections 510 alternating in placement between distal and proximal ends of the filament pairs. In some implementations, the connections 510 between the ends of the filaments 300 can be located outside of the interior space 104.

The intra-chamber electrode assembly 508 can be driven with RF signals in various ways. In some implementations, the subassembly 520 and subassembly 530 are driven with the same RF signal 570, from one corner of the filament structure to the opposite corner. In some implementations, the RF signal is driven with respect to an RF ground.

Referring to FIG. 5E, an intra-chamber electrode assembly 509 includes a first electrode subassembly 520 and a second electrode subassembly 530. The first electrode subassembly 520 and the second electrode subassembly 530 each has multiple parallel filaments 300 that are connected by buses 540 and 550, respectively, at one end. In some implementations, the filaments 300 of the first electrode subassembly are connected to the bus 540 at a proximal end of the filaments, and the filaments 300 of the second electrode subassembly are connected to the bus 550 at an opposite distal end of the filaments.

The first electrode subassembly 520 and the second electrode subassembly 530 are configured such that the filaments of the subassemblies 520 and 530 are arranged in alternating pattern. The filaments 300 can be parallel to each other.

At least some adjacent filament pairs from the subassemblies 520 and 530 are electrically connected in parallel. In particular, the ends of filaments of the first subassembly 520 that are not connected to the buses 540 are instead connected to the ends of the filaments of the second subassembly 530 that are not connected to the bus 550. For example, the electrical connections 510 can be formed between the distal ends of the filaments of subassembly 520 and the proximal ends of the filaments of subassembly 530.

In some implementations, each filament of the first assembly 520 is electrically connected in this manner to a single filament the second subassembly 530. The connections 510 between the ends of the filaments 300 can be located outside of the interior space 104.

The intra-chamber electrode assembly 509 can be driven with RF signals in various ways. In some implementations, the subassembly 520 is driven by input 570, e.g., to bus 540, and subassembly 530 is driven by input 580, e.g., to bus 550. In some assemblies, inputs 570 and 580 are driven with a same RF signal with respect to an RF ground. In some implementations, the subassembly 520 and subassembly 530 are driven with a differential RF signal. In some implementations, the subassembly 520 and subassembly 530 are driven with two different RF signals, of the same, with a phase difference between 0 and 360 degrees. In some implementations, the phase difference is modulated over time.

In general, differential driving of the subassemblies 520, 524 and the respective subassemblies 530, 534 can improve plasma uniformity or process repeatability when an adequate RF ground cannot be provided (e.g., RF ground through a rotary mercury coupler, brushes, or slip rings).

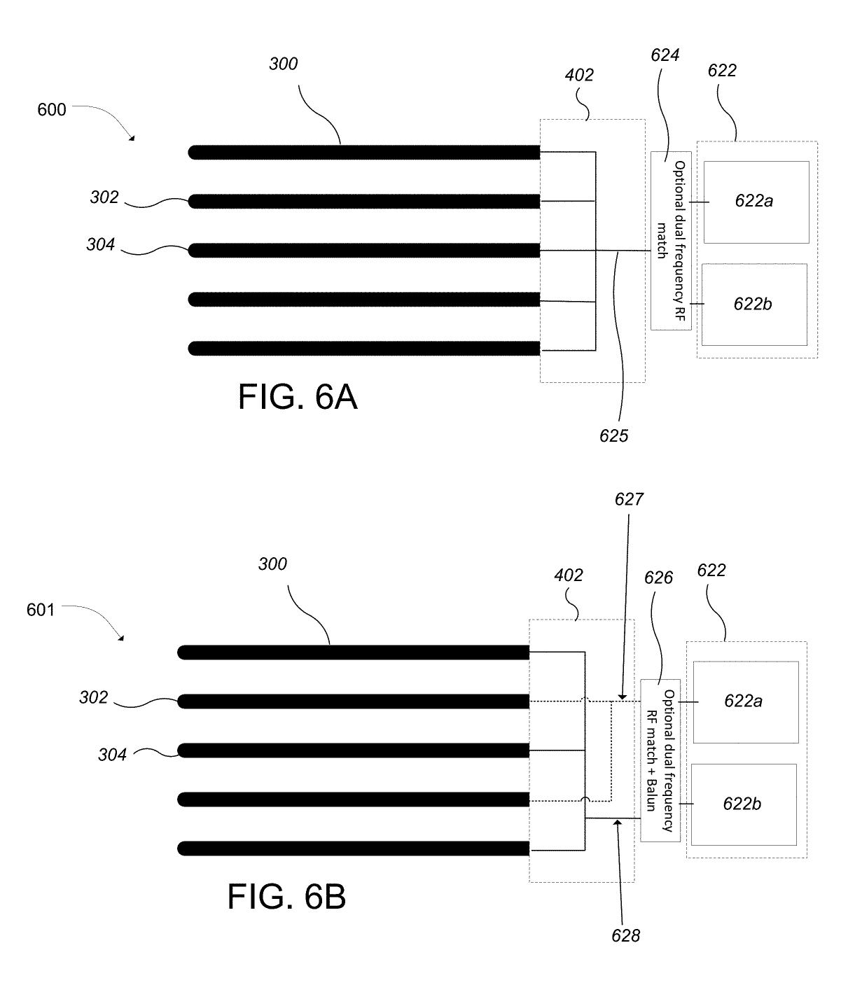

In some implementations, a plasma source may be powered by two or more radio frequency generators, which may operate at different frequencies. FIGS. 6A-6B are schematic diagrams of a portion of an intra-chamber electrode assembly. Referring to FIG. 6A, an intra-chamber electrode assembly 600 includes multiple filaments 300. The electrode assembly 600 can provide the electrode assembly 120, and the filaments 300 can provide the filaments of the electrode assembly 120.

The electrode assembly 600 is powered by two or more radio frequency generators, 622a and 622b. In some implementations, the first RF generator 662a is configured to generate RF power at a frequency of 12 MHz to 14 MHz, e.g., 13.56 MHz, and the second RF generator 662b is configured to generate RF power at a frequency of 57 MHz to 63 MHz, e.g., 60 MHz. Without being bound by any particular theory, if multiple frequency generation is used in semiconductor plasma processing, a higher frequency generator can be used primarily for plasma generation and a lower frequency can be used primarily to increase ion energy or change the ion energy distribution function, e.g., widening the function and extending it to higher energies, by modulating the plasma-to-workpiece potential.

In some implementations, as shown in FIG. 6A, two frequency generators, 622a and 622b, provide inputs into a circuit 624 that includes dual frequency RF impedance matching circuitry and an integrated filter. The single output 625 is applied in parallel to all of the filaments 300. Without being limited to any particular theory, the impedance matching provides increased power transfer from generators to load without interference or damage. The frequency generators 622a and 622b and circuit 624 may be used to supply one of the inputs in any of the assemblies shown in FIGS. 5A-5E.

In some implementations, as shown in FIG. 6B, the intra-chamber electrode assembly 601 can include a first group and a second group of filaments 300. The first group and the second group can be spatially arranged such that the filaments alternate between the first group and the second group. For example, the first group can include filaments 302, the second group can include filaments 304. In some implementations, two frequency generators, 622a and 622b, provide inputs into a circuit 626 that includes dual frequency RF impedance matching circuitry, an integrated filter, and a balun. The circuit 626 may optionally utilize circulators with dummy resistance loads to provide a path to ground for any reflected signal traveling back into the same port. The outputs, 627 and 628, are applied to the first and second filament groups respectively. The output frequencies are identical and 180 degrees apart in phase. Without being limited to any particular theory, the impedance matching provides maximum power transfer from generators to load without interference or damage. The frequency generators 622 and circuit 626 may be used to supply differential inputs in any of the assemblies shown in FIGS. 5A-5E.

In some embodiments, the phase difference between the multiple RF inputs applied to an electrode assembly may be modulated with time.

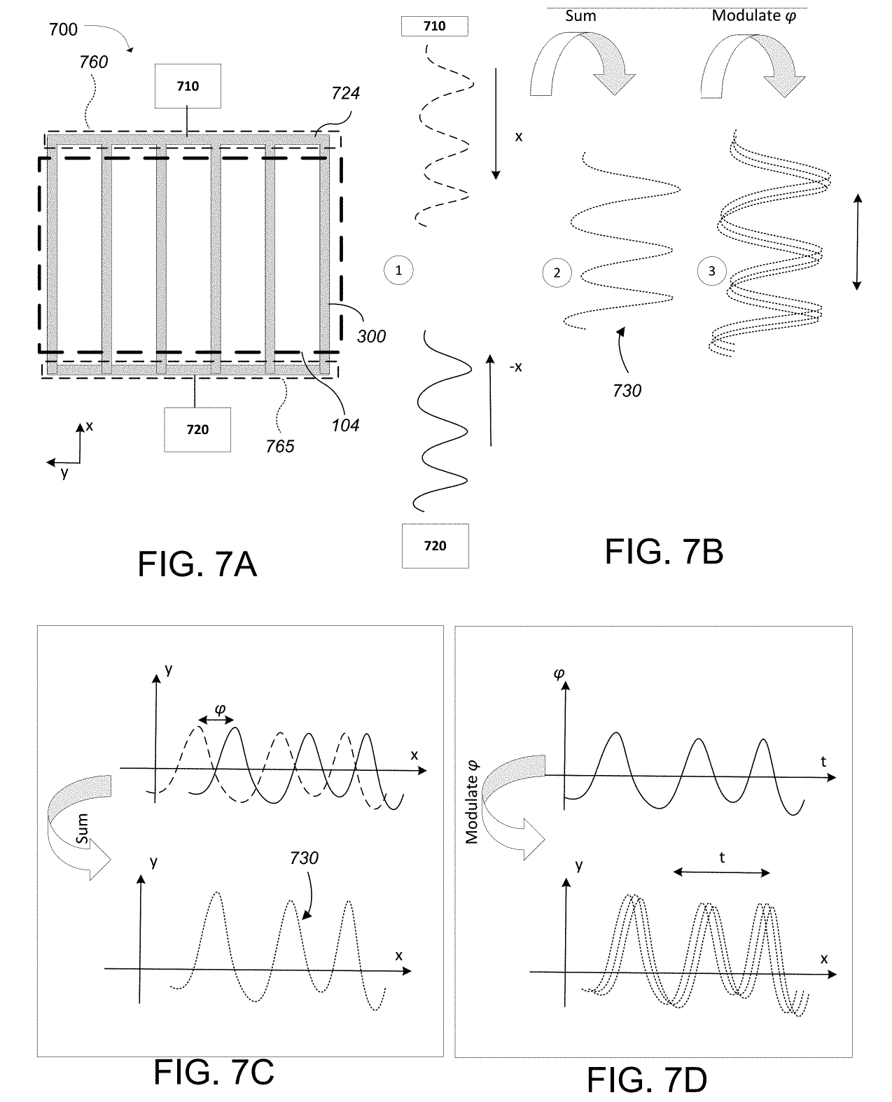

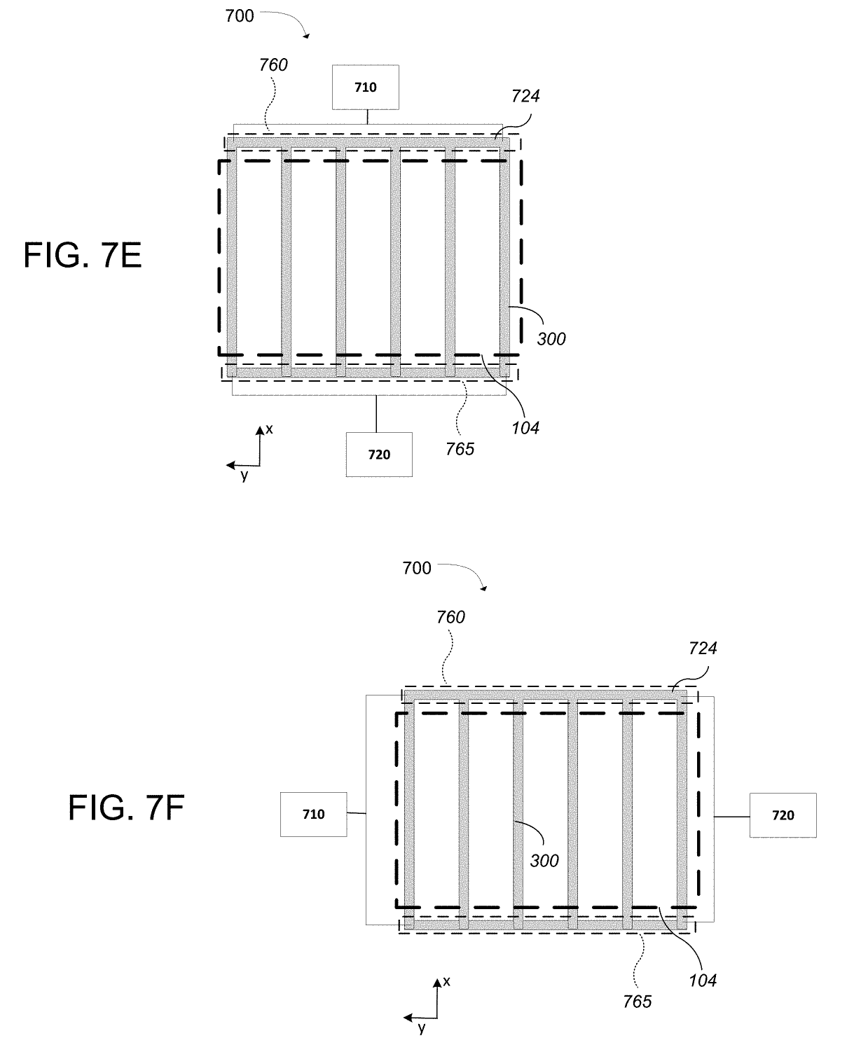

Referring to FIG. 7A, an intra-chamber electrode assembly 700 includes an electrode subassembly 724. The electrode subassembly 724 has multiple filaments 300 that are connected by the buses 760 and 765 at opposite ends. Two RF inputs, 710 and 720, are connected to the buses 760 and 765 respectively

In some implementations, the RF inputs are operated at the same frequency, but the phase difference y between the inputs is modulated over time. For example, the phase difference can be driven as a simple sawtooth wave function, although other functions such as triangle wave function or sinusoidal function are possible. The phase difference can be driven across a full 360 degrees, or across a smaller range, e.g., +/− 180 degrees or for a smaller non-uniformity adjustment range +/− 90 degrees. The range need not be symmetrical about 0 degrees.

In some implementations, one or more of the RF inputs is applied to multiple locations on a bus. In some implementations, the each RF input is applied to multiple points on the same bus, but two RF inputs are applied to buses connected to opposite ends of the filaments. For example, as shown in FIG. 7E, the first input 710 can be applied to opposite ends of the bus 760 and the second input 720 can be applied to opposite ends of the bus 765. In some implementations, each RF inputs is applied to both buses. For example, as shown in FIG. 7F, the first RF input 710 is applied to a first end of each bus 760, 765, and the second RF input 720 is applied to an opposite second end of each bus 760, 765. In addition, rather than both inputs being on the same side (left or right), each RF input could be connected to locations that are catty-corner on the electrode array.

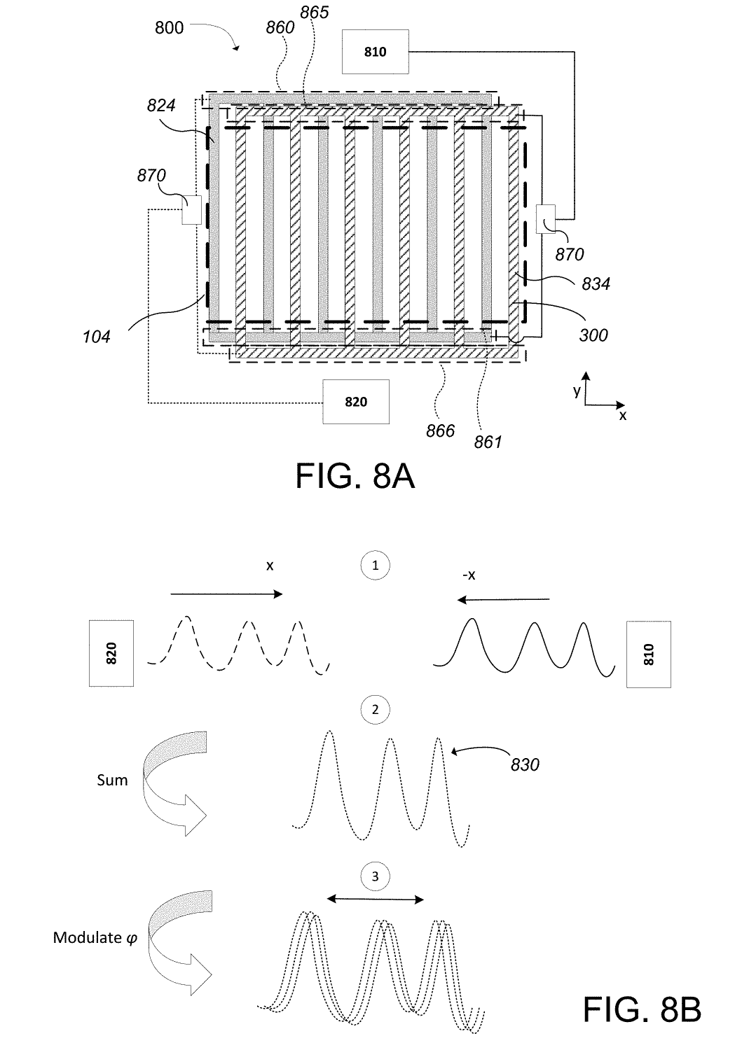

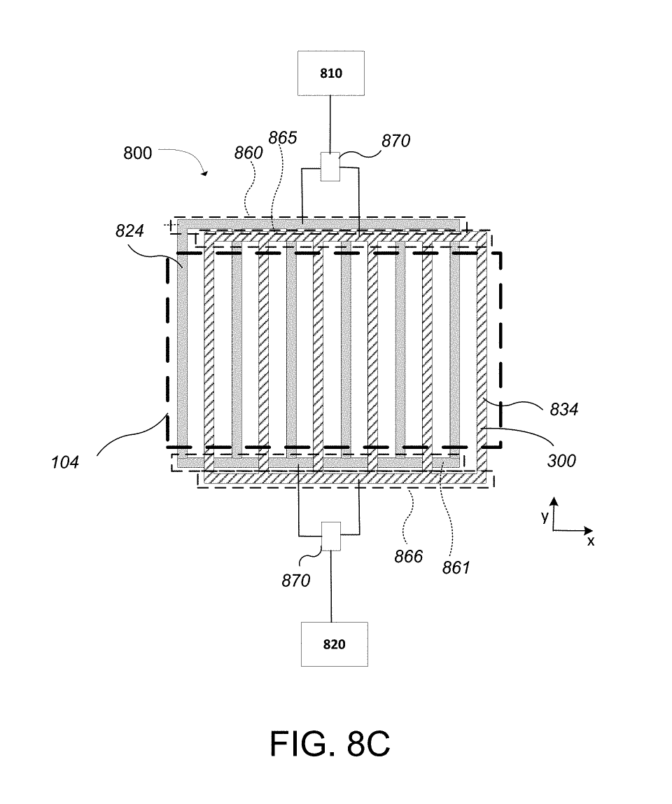

Referring to FIG. 8A, an intra-chamber electrode assembly 800 includes a first electrode subassembly 824 and a second electrode subassembly 834. The electrode assembly 800 can be one of the electrode assemblies or subassemblies discussed with respect to FIGS. 5B and 5E. The first electrode subassembly 824 and the second electrode subassembly 834 each has multiple filaments 300 that are connected by buses 860 and 865 at one end respectively and buses 861 and 866 at the other end respectively. The first electrode subassembly 824 and the second electrode subassembly 834 are configured such that the filaments of the subassemblies 824 and 834 are arranged in alternating pattern. The filaments 300 can be parallel to each other.

In some implementations, the buses 860, 861, 865, and 866 connecting the filaments 300 are located outside of the interior space 104. In some implementations, the buses 860, 861, 865, and 866 connecting the filaments 300 are located in the interior space 104.

In some implementations, the RF input 810 is split into by a balun into a differential signal that includes two RF signals of equal frequency that are offset by 180 degrees. The outputs of the balun 870 can be connected to both electrode subassemblies on the same side of buses 861 and 865. The RF input 820 is split by a balun 8270 into a differential signal that includes two RF signals of equal frequency that are offset by 180 degrees. The outputs of the balun 870 are connected to both electrode subassemblies at the opposite side of buses 860 and 866.

Many other variations are possible to apply the differential signal from the RF inputs 810, 820 to the two electrode subassemblies 824, 834. Rather the different differential RF signals being applied to left and right sides, respectively, the two electrode subassemblies 824, 834, the different differential RF signals can be applied to busses on respective opposite sides of the chamber. For example, referring to FIG. 8C a first differential RF signal 820 could be applied to busses 860, 861 on one side of the chamber 104, and a second differential RF signal 820 could be applied to busses 865, 866 on an opposite side of the chamber 104. Moreover, rather than being connected to a single location on each bus, the RF signals can be applied at multiple locations on each bus, e.g., at opposite ends of each bus.

In some implementations, the RF inputs 710, 720 or 810, 820 are operated at the same frequency, but the phase difference y between the inputs is modulated over time. For example, the phase difference can be driven as a simple sawtooth wave function, although other functions such as triangle wave function or sinusoidal function are possible. The phase difference can be driven across a full 360 degrees, or across a smaller range, e.g., +/− 180 degrees or for a smaller non-uniformity adjustment range +/− 90 degrees. The range need not be symmetrical about 0 degrees.

The frequency for the phase modulation can be selected over a wide range. For example, if only time average uniformity is important, low modulation frequencies may be used, e.g. 1 Hz, up to 10 kHz, or 100 KHz, limited by modulating capability, phase slew rate, or bandwidth of the generator at the high end. When instantaneous plasma uniformity is important (for device damage minimization), then higher modulation frequencies may be used, e.g., 100 Hz to 10 KHz or 100 KHz or higher, e.g., 1 kHz-10 KHz or 100 KHz or higher.

With respect to the various phase modulation schemes, this modulation can improve uniformity of the plasma density. Without being limited to any particular theory, phase modulation can minimize the voltage non-uniformity, or voltage standing wave ratio, across the electrode array, thus minimizing plasma non-uniformity. For example, modulation of the phase difference of the input signals can cause standing waves of RF energy on the filaments to shift over time, such that the time averaged voltage (and thus plasma density) is more uniform.

Again without being bound by any particular theory, FIGS. 7B-D details one possible mechanism for phase modulation in the assembly shown in FIG. 7A. FIG. 7B(1) and FIG. 7C show two signals from inputs 710 and 720 of the same frequency and phase difference φ applied to opposite ends of the assembly. The two signals add to form standing wave 730 as shown in FIG. 7B(2) and FIG. 7C. As the phase difference φ of the two inputs is modulated over time, as shown in FIG. 7D and FIG. 7B(3), the standing wave 730 is spatially modulated over the electrode assembly filaments.

Similarly without being bound by any particular theory, FIG. 8B details one possible mechanism for phase modulation in the assembly shown in FIG. 8A. FIG. 8B shows two signals from inputs 810 and 820 of the same frequency and phase difference φ applied to opposite ends of the assembly. The two signals add to form standing wave 830 as shown in FIG. 8B(2). As the phase difference φ of the two inputs is modulated over time, as shown in FIG. FIG. 8B(3), the standing wave 830 is spatially modulated over the electrode assembly filaments.

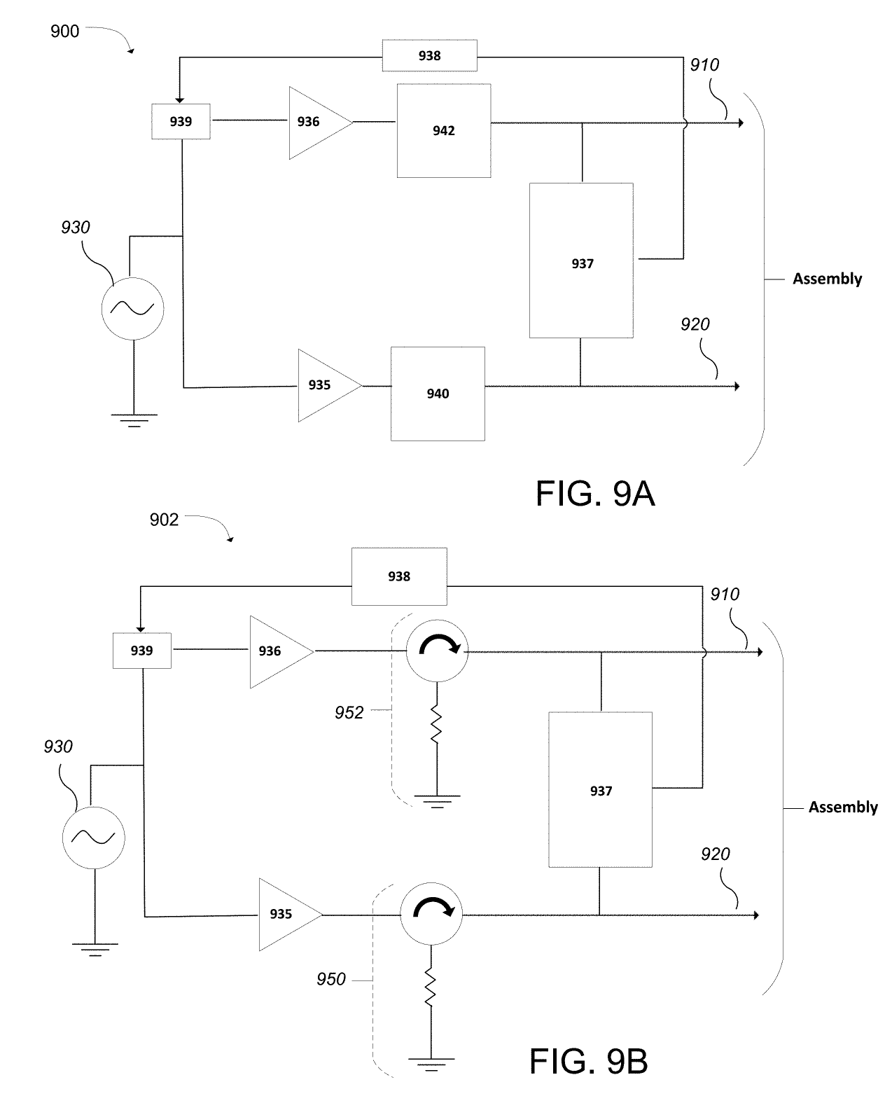

Signals of the same frequency for phase modulation may be generated in a number of ways. FIGS. 9A-9B show two exemplary circuits 900 and 902 for generating outputs 910 and 920 that can provide inputs 710 and 720 in FIG. 7A or inputs 810 and 820 in FIG. 8A. Signal inputs for circuit 900 and 902 originate at an RF reference signal generator 930. The signal from the generator 930 is amplified by a master RF amplifier 935 to generate the first output 910. The signal from the generator 930 is also sent to a phase shifter 939. The phase shifter 939 generates a phase shifted output which is amplified by a slave RF amplifier 936 to generate the second output 920. The outputs of the master RF amplifier 935 and the slave RF amplifier are fed to a phase detector 937, which outputs a signal representative of the phase difference. The signal from the phase detector 937 is fed to a phase controller 938 which controls the phase shifter 939, thus providing a feedback loop. The phase controller 938 and shifter 937 can modulate the phase difference between outputs from the master 920 and the slave 910 as a function of time as detailed above.

In FIG. 9A, impedance match circuitries 940 and 942 are placed between the output of the master 935 and slave 936 generators and the phase detector 937 respectively. The impedance match circuitries 940 and 942 prevent reflections of signals coming into the circuit 900 from the electrode assembly connected at outputs 910 or 920, for example from electrode assembly 700 or 800. Without being limited to a particular theory, reflections from the circuit 900 may cause formation of undesired standing waves or other interference at the electrode assembly.

In FIG. 9B, circulators connected to dummy loads 950 and 952 are placed between the output of the master 935 and slave 936 generators and the phase detector 937 respectively. The circulator and load circuitries 950 and 952 allow signals coming into the circuit 902 from the electrode assembly connected at outputs 910 or 920, for example from assembly 700 or 800, to be absorbed in a dummy load termination instead of propagating to the signal generator 930 or reflecting back into plasma source region. Alternatively, isolators may substitute the circulators connected to dummy loads 950 and 952. Isolators would likewise prevent signal from traveling from the assembly back towards the signal generator 930. A first matching network may be connected between point 910 and the first input tap of the electrode array, and a second matching network may be connected between point 920 and the second input tap on the electrode array. Without being limited to a particular theory, this mechanism prevents damage to the generator and signal interference.

In some implementations, the phase modulation can be used to deliberately introduce non-uniformity into the plasma density. For example, it may be desirable to induce a plasma density non-uniformity to compensate for a non-uniformity of a layer on the substrate or a source of non-uniformity of processing of the layer. For such implementation, a skewed wave function can be applied to drive the phase difference, so that the nodes have longer dwell time at regions where plasma density is otherwise too high, and anti-nodes have longer dwell time at regions where plasma density is otherwise too low.

In some implementations, signals 910 and 920 with modulated phase can be applied to electrode assemblies that are not electrically connected, such as inputs 570 and 580 in FIGS. 5A-5C. In that case, phase modulation between the two input signals can be used to control the location of the plasma in the chamber 104 with respect to time. Thus, processing conditions may be temporally controlled.

Without being limited to any particular theory, phase modulation may be used to control inherent non-uniformity of the plasma over the workpiece caused by, for example, reflections due to impedance mismatch or physical constraints of the system. For example, temporal modulation of the voltage pattern may result in improved time averaged uniformity of the plasma applied to the workpiece, potentially reducing the effect of inherent plasma non-uniformity.

In some implementations, rather than applying phase modulated standing wave signals to the embodiments, traveling wave inputs may be applied to an electrode assembly. Without being bound by any particular theory, if multiple inputs are applied to different parts of an electrode array which is terminated to generate traveling waves, then the frequency between the inputs must be different in order to prevent the two inputs from interfering and forming a standing wave.

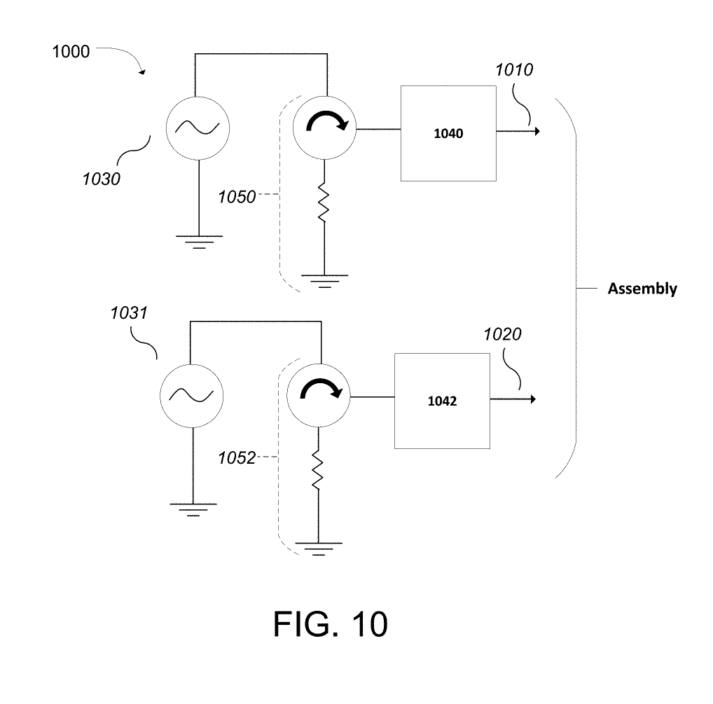

FIG. 10 shows an exemplary circuit 1000 for generating outputs 1010 and 1020 that can provide inputs 710 and 720 in FIG. 7A, 7E or 7F or inputs 810 and 820 in FIGS. 8A or 8C. Two frequency generators 1030 and 1031 provide signals of two different frequencies. Signal from the first generator 1030 travels through a circulator with a first dummy load 1050 and a first impedance match 1040 to produce a first output 1010. Similarly, the signal from the second generator 1031 travels through a second circulator with a second dummy load 1052 and a second impedance match 1042 to produce a second output 1020. The circulator and load circuitries 1050 and 1052 allow any signals coming into the circuit 1000 from the electrode assembly connected at outputs 1010 or 1020, for example from assembly 700 or 800, to be absorbed in a dummy load termination instead of propagating to the signal generator 1030 or 1031 or reflecting back into plasma source region.

Alternatively, isolators may substitute the circulators connected to dummy loads 1050 and 1052. Isolators would likewise prevent signal from traveling from the assembly back towards the signal generators 1030, 1031. Without being limited to a particular theory, the circulators and loads 1050 and 1052 or alternative isolators prevent damage to the generator and signal interference.

The impedance match circuitries 1040 and 1042 prevent reflections of signals coming into the circuit 1000 from the electrode assembly connected at outputs 1010 or 1020, for example from electrode assembly 700 or 800. Without being limited to a particular theory, reflections from the circuit 1000 may cause formation of undesired standing waves or other interference at the electrode assembly.

In some implementations, the frequency difference between outputs of generators 1030 and 1031 may be selected such that both frequencies are within the bandwidth of the circulator (or isolator) units 1050, 1052 and within the bandwidth of the matching circuitries 1040 and 1042. In some implementations, the frequency difference is 1 Hz up to several MHz, preferably 1 kHz to 10's of kHz or 100's of kHz. For example, the frequencies can be 59.9 GHz and 60.1 GHz. In some embodiments, the frequency difference is chosen to avoid forming a beat pattern, which may produce undesirable non-uniformity in the traveling wave.

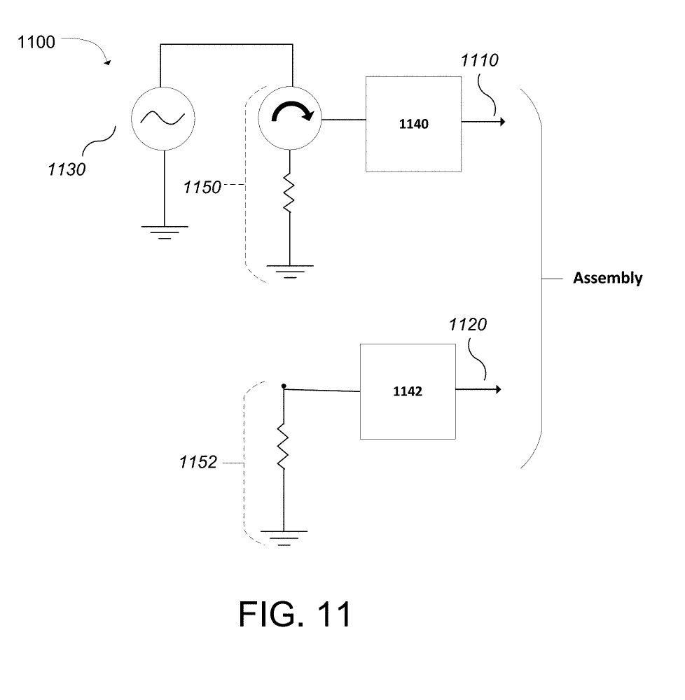

If multiple frequency generators are not available, then a traveling wave may be generated with a single input, as shown in FIG. 11. FIG. 11 shows an exemplary circuit 1100 with two output ports 1110 and 1120. These ports can be connected to inputs 710 and 720 in FIGS. 7A, 7E or 7F or inputs 810 and 820 in FIGS. 8A or 8C. One frequency generator 1130 provides a single RF frequency signal. Signal from the generator 1130 travels through a circulator with a first dummy load 1150 and a first impedance match 1140 to produce an output at port 1010. Signal from this port travels through the connected electrode assembly, e.g., 700 or 800, and enters port 1120 at the other side of the electrode assembly, where it encounters a second impedance match 1142 and a second dummy load 1152. The circulator and load circuitries 1150 and 1152 allow any signals coming into the circuit 1100 from the electrode assembly connected at ports 1110 or 1120, for example from assembly 700 or 800, to be absorbed in a dummy load termination instead of propagating to the signal generator 1130 or reflecting back into plasma source region.

Alternatively, isolators may substitute the circulators connected to dummy loads 1150 and 1152. Isolators would likewise prevent signal from traveling from the assembly back towards the signal generator 1130. Without being limited to a particular theory, the circulators and loads 1150 and 1152 or alternative isolators prevent damage to the generator and signal interference.

The impedance match circuitries 1140 and 1142 prevent reflections of signals coming into the circuit 1100 from the electrode assembly connected at outputs 1110 or 1120, for example from electrode assembly 700 or 800. Without being limited to a particular theory, reflections from the circuit 1100 may cause formation of undesired standing waves or other interference at the electrode assembly.

Without being limited to any particular theory, using a single or multiple inputs to generate traveling waves across an electrode assembly helps mitigate the effect of inherent non-uniformity of the plasma over the workpiece caused by, for example, reflections due to impedance mismatch or physical constraints of the system. For example, traveling waves result in temporal and spatial variations in voltage over the electrode, resulting in improved time averaged uniformity of the plasma applied to the workpiece, potentially reducing the effect of inherent plasma non-uniformity. Multiple inputs may allow for improved performance as multiple traveling waves can generate a more uniform time averaged voltage profile than a single traveling wave.

Without being limited to any particular theory, phase modulation allows the user greater control in adjusting the voltage profile over the electrode assembly because the phase difference can be driven by any pattern as a function of time. Phase modulation is more time consuming to set up and more costly, however, as it requires a phase-locking feedback mechanism. In contrast, generation of traveling waves requires no feedback mechanism and is thus simpler and cheaper. However, traveling wave setups do not allow temporal control of the signal.

Particular embodiments have been described, but other embodiments are possible. For example:
Although some implementations are illustrated as having the RF power applied to the middle of a bus, RF power could be applied to one or both ends or other locations on the bus.
Multiple frequencies can be applied in conjunction with phase modulation. For example, a first pair of RF signals with two different frequencies can be applied to a first electrode subassembly, and a second pair RF signals with the same two frequencies can be applied to the other electrode subassembly or to a different location of the first electrode subassembly. Then one or both RF signals from the second RF pair can be phase modulated relative to the respective RF signal in the first RF pair.

Other embodiments are within the scope of the following claims.

1. A plasma reactor comprising:
a chamber body having an interior space that provides a plasma chamber;
a gas distributor to deliver a processing gas to the plasma chamber;
a pump coupled to the plasma chamber to evacuate the chamber;
a workpiece support to hold a workpiece;
an intra-chamber electrode assembly comprising a plurality of filaments extending laterally through the plasma chamber between a ceiling of the plasma chamber and the workpiece support, each filament including a conductor surrounded by a cylindrical insulating shell, and
an RF power source configured to apply a first RF signal to at least some of the plurality of filaments, to apply a second RF signal of equal frequency to at least some of the plurality of filaments, and to modulate a phase offset between the first RF signal and the second RF signal.

2. The plasma reactor of claim 1, wherein the plurality of filaments have a plurality of first ends and a plurality of second ends, and wherein a first end of each respective filament is closer to a first sidewall of the plasma chamber than a second end of the respective filament.

3. The plasma reactor of claim 2, wherein the first RF signal is applied to the first ends of the plurality of filaments, and the second RF signal is applied to the second ends of the plurality of filaments.

4. The plasma reactor of claim 3, wherein the first ends of the plurality of filaments are connected to a first common bus, and the second ends of the plurality of filaments are connected to a second common bus.

5. The plasma reactor of claim 2, wherein the plurality of filaments include a first filament, a plurality of intermediate filaments, and a final filament, wherein the first RF signal is applied to the first filament, and the second RF signal is applied to the final filament, and each intermediate filament has a first end electrically connected to a second end of an adjacent filament and a second end electrically coupled to a first end of another adjacent filament.

6. The plasma reactor of claim 2, wherein the plurality of filaments includes a first multiplicity of filaments and a second multiplicity of filaments arranged in an alternating pattern with the first multiplicity of filaments, and wherein the first RF signal is applied to the first multiplicity of filaments and the second RF signal is applied to the second multiplicity of filaments.

7. The plasma reactor of claim 6, wherein the RF power source is configured to apply the first RF input signal to the first ends of the first multiplicity of filaments an to apply the second RF signal to the second ends of the second multiplicity of filaments.

8. The plasma reactor of claim 7, wherein second ends of the first multiplicity of filaments are floating and first ends of the second multiplicity of filaments are floating.

9. The plasma reactor of claim 7, wherein the second ends of the first multiplicity of filaments are grounded and the first ends of the second multiplicity of filaments are grounded.

10. The plasma reactor of claim 6, wherein the second ends of the first multiplicity of filaments are electrically connected to the first ends of the second multiplicity of filaments.

11-12. (canceled)

13. The plasma reactor of claim 1, wherein the plurality of filaments comprise a first multiplicity of filaments, and comprising a first bus connected to first ends of the first multiplicity of filaments.

14. The plasma reactor of claim 13, wherein the RF power source is configured to apply the first RF signal to a first location on the first bus and to apply the second RF signal to a different second location on the bus.

15. The plasma reactor of claim 14, wherein the first location and the second location are on opposite ends of the bus.

16. The plasma reactor of claim 13, comprising a second bus connected to opposite second ends of the first multiplicity of filaments.

17. The plasma reactor of claim 13, wherein the RF power source is configured to apply the first RF signal to a first location on the first bus and to apply the second RF signal to a different second location on the second bus.

18. The plasma reactor of claim 17, wherein the RF power source is configured to apply the first RF signal to a different third location on the first bus and to apply the second RF signal to a different fourth location on the second bus.

19. The plasma reactor of claim 13, wherein the plurality of filaments comprises a second multiplicity of filaments, and comprising a third bus connected to first ends of the second multiplicity of filaments.

20. The plasma reactor of claim 19, wherein the RF power source is configured to apply the first RF signal to a first location on the first bus and a second location on the third bus, and to apply the second RF signal to a different third location on the first bus and a different fourth location on the third bus.

21. The plasma reactor of claim 19, comprising a second bus connected to opposite second ends of the first multiplicity of filaments and a fourth bus connected to opposite second ends of the second multiplicity of filaments.

22. The plasma reactor of claim 21, wherein the RF power source is configured to apply the first RF signal to a first location on the first bus and a second location on the second bus, and to apply the second RF signal to a third location on the third bus and a fourth location on the fourth bus.

23. The plasma reactor of claim 21, wherein the RF power source is configured to apply the first RF signal to a first location and a different second on the first bus and to a third location and a different fourth location on the second bus, and to apply the second RF signal to a fifth location and a different sixth location on the third bus and to a seventh location and a different eighth location on the fourth bus.

24. The plasma reactor of claim 23, wherein the first, third, fifth and seventh locations are on opposite ends of respective busses from the second, fourth, sixth and eighth locations, respectively.

25. The plasma reactor of claim 1, wherein the RF power source is configure to modulate the phase offset so as to vary a standing wave pattern of voltage on the conductors over time.

26-29. (canceled)

30. A method of processing a workpiece, comprising:
positioning the workpiece on a workpiece support such that a front surface of the workpiece faces a plurality of filaments that extend laterally through a plasma chamber between a ceiling of the plasma chamber and the workpiece support;
delivering a process gas to the plasma chamber;
applying a first RF signal to at least some of the plurality of filaments and applying a second RF signal of equal frequency to at least some of the plurality of filaments so as to generate a plasma in the plasma chamber and the workpiece is exposed to the plasma from the plasma chamber; and
modulating a phase offset between the first RF signal and the second RF signal.

31-35. (canceled)
